(19) United States
(12) Patent Application Publication
(10) Pub. No.: US 2005/0153565 A1
(43) Pub. Date: Jul. 14, 2005

(54) Methods of manufacturing semiconductor devices

(76) Inventor: In Hyeck Baik, Icheon-si (KR)

Correspondence Address: HANLEY, FLIGHT & ZIMMERMAN, LLC, 20 N. WACKER DRIVE, SUITE 4220, CHICAGO, IL, 60606, US

(21) Appl. No.: 11/023,260

(22) Filed: Dec. 27, 2004

(30) Foreign Application Priority Data
Dec. 27, 2003 (KR) 10-2003-0098055

(51) Int. Cl. H01L 21/302; H01L 21/461

(52) U.S. Cl. 438/719

(57) ABSTRACT

Methods for manufacturing a semiconductor device are disclosed. One example method includes transferring and loading a substrate with a photoresist pattern thereon in an etching apparatus; setting the temperature of the substrate to a temperature suitable for an etching process by passing the substrate through at least one predetermined chamber; and loading the substrate in an etching chamber and performing an etching process.

### TECHNICAL FIELD

The present disclosure relates generally to semiconductor devices and, more specifically, to methods of manufacturing semiconductor devices.

### BACKGROUND

With the high-integration of semiconductor devices, stabilization of semiconductor fabrication processes, as well as stabilization of process apparatuses are desperately required. Particularly, problems caused by particles are very serious and in order to obviate such problems various technologies have been developed.

In manufacturing semiconductor devices, to make a predetermined layer pattern, a photoresist layer is formed on a thin layer on a semiconductor substrate. A dry etching or a wet etching is then performed using the photoresist layer as a mask. After the completion of the etching process, the photoresist layer is removed by a dry or wet process. The etching process is carried out using the gas of a plasma state. Therefore, the critical dimension (CD) of the formed layer pattern is controlled by the volume of an etching gas such as Cl₂ and F₂, and the amount of used polymer such as Cₓ, CₓHₓ and CₓHₓFₓ. The CD of layer pattern may also be controlled by RF power, process pressure, process temperature, etc. Most of all, however, the CD of layer pattern is greatly influenced by the temperature in an etching chamber, particularly, the temperature in the lower part of etching chamber on which the substrate is positioned.

However, in the conventional etching process in which the CD is controlled by temperature, problems result from particles such as re-deposition of photoresist polymer in the lower part of etching chamber. In addition, the frequent temperature changes impose high stresses on the photoresist polymer re-deposited in the etching chamber. Such stresses result in the cracking of the re-deposited polymer, thereby shortening the wet cleaning cycle of an apparatus. Moreover, it is difficult to raise or lower the temperature of the substrate in the etching chamber to a desired temperature because the etching process begins within a few seconds of the substrate being transferred into the etching chamber and positioned on an electro static chuck (ESC).

### BRIEF DESCRIPTION OF THE DRAWINGS

FIGS. 1 through 4 are cross-sectional views of semiconductor devices at various stages of a disclosed fabrication process.

### DETAILED DESCRIPTION

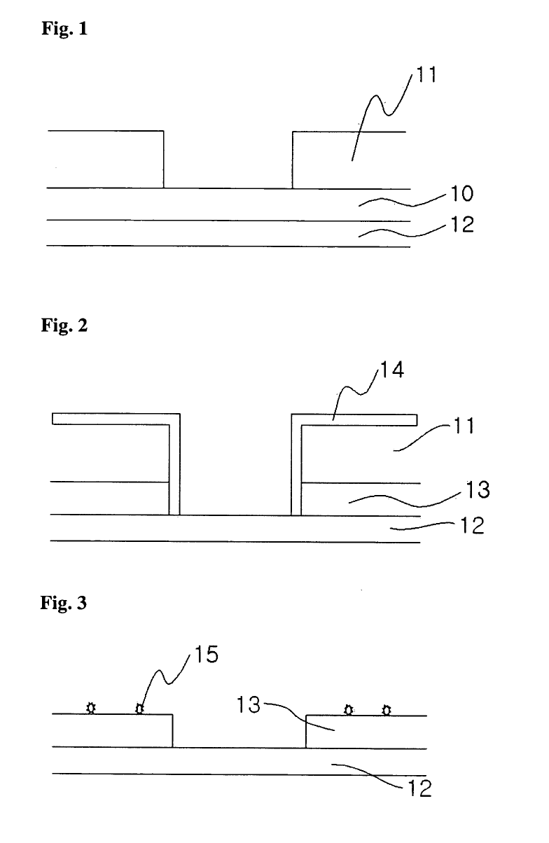

Referring to FIG. 1, a substrate having a photoresist pattern thereon is transferred and loaded in an etching apparatus, and heated or cooled to a predetermined temperature as it is passed through at least one chamber. In detail, as shown in FIG. 1, a substrate 12 is prepared. A predetermined thin layer 10 and a photoresist pattern 11 are formed on the substrate 12. The substrate 12 with the photoresist pattern 11 is loaded, by a transfer device, into an etching apparatus equipped with an etching chamber. The temperature of the substrate 12 is set to a temperature suitable for an etching process during passing through at least one predetermined chamber. The predetermined chamber may be at least one chamber through which the substrate passes prior to the etching process, such as a stage chamber through which the substrate passes immediately before it is loaded in the etching chamber, an align chamber in which the substrate is aligned, and a transfer chamber in which the substrate is transferred.

The temperature of the substrate 12 is set to provide cooling or heating. Generally, the process for etching the thin layer is performed at a temperature between about −20° C. and about 80° C. The temperature less than about 30° C. is controlled by a chiller using antifreeze such as a coolant to maintain a constant temperature, or by integrated circuits. The temperature between about 20° C. and about 80° C. is controlled by a heater using electric heat provided by heating wires. In on example, a nitrogen gas may be used to improve heat transfer in the predetermined chamber. Such an arrangement enables the temperature of substrate 12 to reach a predetermined temperature within a short time.

Referring to FIG. 2, the substrate 12 at the predetermined temperature is loaded in the etching chamber. The thin layer is etched using the photoresist pattern 11 as a mask to form a predetermined layer pattern 13 on the substrate 12. Generally, polymer residuals due to the photoresist pattern 11 may be re-deposited as by-products 14 on the surface of the resulting structure during the etching process. The re-deposition of the polymer residuals particularly occurs at the place with the lowest temperature in the etching chamber. However, the illustrated example process greatly reduces the re-deposition of the polymer residuals by controlling the temperature of substrate 12 to a predetermined process temperature before the etching process begins.

Referring to FIG. 3, the photoresist pattern is removed by using an ashing process. However, the ashing process may not completely remove the photoresist pattern to leave some polymer residuals 15 on the resulting structure.

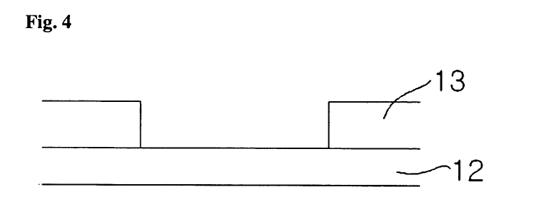

Referring to FIG. 4, the polymer residuals 15 are completely removed by using a wet cleaning process. The wet cleaning process uses a solution comprising sulfuric acid and hydrogen peroxide.

From the foregoing, persons of ordinary skill in the art will appreciate that, by performing an etching process after controlling the temperature of a substrate to an appropriate temperature in at least one predetermined chamber, the disclosed methods achieve the uniformity of the CD of a layer pattern formed, reduce the defects due to particles, improve operating ratios by ensuring the stability of an apparatus, and increase a wet cleaning cycle by decreasing apparatus contamination.

It is noted that this patent claims priority from Korean Patent Application Serial Number 10-2003-0098055, which was filed on Dec. 27, 2003, and is hereby incorporated by reference in its entirety.

Although certain example methods, apparatus, and articles of manufacture have been described herein, the scope of coverage of this patent is not limited thereto. On the contrary, this patent covers all methods, apparatus, and articles of manufacture fairly falling within the scope of the appended claims either literally or under the doctrine of equivalents.

1. A method for manufacturing a semiconductor device comprising:
transferring and loading a substrate with a photoresist pattern thereon in an etching apparatus;
setting the temperature of the substrate to a temperature suitable for an etching process by passing the substrate through at least one predetermined chamber; and
loading the substrate in an etching chamber and performing an etching process.

2. A method as defined by claim 1, further comprising removing the photoresist pattern using an ashing process and a wet cleaning process after the etching process.

3. A method as defined by claim 2, wherein the wet cleaning process uses a solution comprising sulfuric acid and hydrogen peroxide.

4. A method as defined by claim 2, wherein the predetermined chamber is a stage chamber through which the substrate passes immediately before the substrate is loaded in the etching chamber.

5. A method as defined by claim 2, wherein the predetermined chamber is an align chamber in which the substrate is aligned.

6. A method as defined by claim 2, wherein the predetermined chamber is a transfer chamber in which the substrate is transferred.

7. A method as defined by claim 2, wherein setting the temperature of the substrate to a temperature suitable for the etching process is performed using nitrogen gas.

8. A method as defined by claim 2, wherein the temperature suitable for the etching process is between about −20° C. and about 80° C., wherein the temperature less than about 30° C. is controlled by a method using a chiller or integrated circuits and the temperature between about 20° C. and about 80° C. is controlled by a method using a heater with electric heating wires.

9. A method as defined by claim 1, wherein the predetermined chamber is a stage chamber through which the substrate passes immediately before the substrate is loaded in the etching chamber.

10. A method as defined by claim 1, wherein the predetermined chamber is an align chamber in which the substrate is aligned.

11. A method as defined by claim 1, wherein the predetermined chamber is a transfer chamber in which the substrate is transferred.

12. A method as defined by claim 1, wherein setting the temperature of the substrate to a temperature suitable for the etching process is performed using nitrogen gas.

13. A method as defined by claim 1, wherein the temperature suitable for the etching process is between about −20° C. and about 80° C., wherein the temperature less than about 30° C. is controlled by a method using a chiller or integrated circuits and the temperature between about 20° C. and about 80° C. is controlled by a method using a heater with electric heat wires.
